(19) United States
(12) Patent Application Publication
(10) Pub. No.: US 2017/0125490 A1
(43) Pub. Date: May 4, 2017

(54) PIXEL ARRAY AND DISPLAY PANEL HAVING THE PIXEL ARRAY

(71) Applicant: EVERDISPLAY OPTRONICS (SHANGHAI) LIMITED, SHANGHAI CITY (CN)

(72) Inventors: Zhi LI, SHANGHAI CITY (CN); Guifang LI, SHANGHAI CITY (CN); Xin MOU, SHANGHAI CITY (CN); Yanhu LI, SHANGHAI CITY (CN)

(73) Assignee: EVERDISPLAY OPTRONICS (SHANGHAI) LIMITED, SHANGHAI CITY (CN)

(21) Appl. No.: 15/179,050

(22) Filed: Jun. 10, 2016

(30) Foreign Application Priority Data
Nov. 3, 2015 (CN) 201510734464.X

(51) Int. Cl. H01L 27/32

(52) U.S. Cl. CPC H01L 27/3218; H01L 27/3216

(57) ABSTRACT

The present disclosure relates to a pixel array and a display panel having the pixel panel. The pixel array is formed on a non-rectangular substrate, and includes: a plurality of edge pixels arranged at an edge of the non-rectangular substrate, each of which has a first boundary facing a boundary of the non-rectangular substrate, wherein the first boundary has a shape adaptive to a shape of the edge of the non-rectangular substrate; and a plurality of center pixels surrounded by the plurality of edge pixels. The pixel array and display panel can improve display effect at boundaries of a non-rectangular OLED display panel.

### CROSS-REFERENCE TO RELATED APPLICATIONS

This application claims priority to Chinese Patent Application No. 201510734464.X, filed Nov. 3, 2015, the entire contents of which are incorporated herein by reference.

### TECHNICAL FIELD

The present disclosure generally relates to display technologies, and more particularly to a pixel array and a display panel having the pixel array.

### BACKGROUND

Recently, with rapid development, Organic Light Emitting Diode (OLED) technology has become the most promising technology which may replace Liquid Crystal Displays (LCDs).

As compared with OLED display panels which have conventional shapes, OLED display panels having abnormal shapes such as non-rectangular shapes have novel structures and thus can be manufactured according to actual requirements. However, unlike conventional rectangular shapes, the OLED display panels having abnormal shapes are not simply formed with right angles and straight lines, and thus if boundaries of the display panels are not designed reasonably, the display effect of the whole product will be influenced.

During manufacturing of the OLED display panels having conventional shapes, pixels generally have a rectangular shape. Due to technology limitations, pixels cannot be manufactured as infinitely small. As a result, the shapes of pixels will influence the light emitting effect at the boundaries of the display device. In conventional OLED display device having a rectangular shape, on the one hand, the area of the display panel is relatively large and the shapes of pixels have unobvious influence on the light emitting effect of the whole panel, and on the other hand, the boundary shapes are similar to the shapes of the pixels in the conventional display panels, both of which are rectangular, and thus the shapes of pixels have small influence on the light emitting effect. However, small sized non-rectangular display panels are seriously influenced by the shapes of the pixels, which can directly influence the light emitting effect at the boundaries of the display panel. In particular, when the shapes of the pixels are greatly different from that of the OLED display panel, the light emitting effect at the boundaries of the OLED display panel will be influenced by the light emitting profile of the pixels. For example, in a small sized circular OLED display panel having pixels of square shapes, sawteeth light emitting effect will occur at the light emitting boundaries of the OLED display panel.

Thus, changing the shapes and arrangement of pixels in non-rectangular OLED display panels becomes a solution for improving display effect of the non-rectangular OLED display panels.

### SUMMARY

Aiming at the defects existing in conventional technologies, embodiments of the present disclosure provide a pixel array which is capable of improving display effect at boundaries of a non-rectangular OLED display panel, and a display panel having the pixel array.

According to an aspect of embodiments of the present disclosure, there is provided a pixel array, formed on a non-rectangular substrate and including:

a plurality of edge pixels arranged at an edge of the non-rectangular substrate, each of which has a first boundary facing a boundary of the non-rectangular substrate, wherein the first boundary has a shape adaptive to a shape of the edge of the non-rectangular substrate; and

a plurality of center pixels surrounded by the plurality of edge pixels.

Optionally, distances between respective first boundaries of the edge pixels and the boundary of the non-rectangular substrate which is adjacent to the first boundaries are substantially the same.

Optionally, the non-rectangular substrate has a polygonal shape, and the first boundaries of the edge pixels are in parallel with the boundary of the non-rectangular substrate which is adjacent to the first boundaries.

Optionally, the boundary of the non-rectangular substrate is curved, and respective first boundaries of the edge pixels adjacent to the curved boundary are of the same curvature as that of the curved boundary.

Optionally, imaginary connection lines for connecting respective first boundaries of the edge pixels are adaptive to a shape of the non-rectangular substrate.

Optionally, distances between at least a part of the imaginary connection lines for connecting the first boundaries of the edge pixels and the boundary of the non-rectangular which is adjacent to the imaginary connection lines are substantially the same.

Optionally, the non-rectangular substrate has a polygonal shape, at least a part of the imaginary connection lines for connecting the first boundaries of the edge pixels are in parallel with the boundary of the non-rectangular substrate which is adjacent to the imaginary connection lines.

Optionally, the boundary of the non-rectangular substrate is curved, and the imaginary connection lines for connecting the first boundaries of the edge pixels adjacent to the curved boundary are of the same curvature as that of the curved boundary.

Optionally, the plurality of edge pixels have the same shape as that of the non-rectangular substrate.

Optionally, the plurality of center pixels have the same shape as that of at least part of the plurality of edge pixels.

Optionally, each of the pixels is composed of three sub-pixels of three different colors.

Optionally, the three different colors are red, blue and green.

Optionally, the number of the blue sub-pixels is greater than either of the number of the green sub-pixels and the number of the red sub-pixels.

Optionally, an area of each the blue sub-pixel is greater than either of an area of each green sub-pixel and an area of each red sub-pixel.

Optionally, at least a part of the sub-pixels are of the same shape as that of the pixels which are composed of the sub-pixels.

According to another aspect of embodiments of the present disclosure, there is provided a display panel, including:

a non-rectangular substrate having the same shape as that of the display panel;

and

the pixel array as mentioned above formed on the non-rectangular substrate.

In the pixel array and display panel of the present disclosure, shapes and arrangement of pixels are changed to make shapes of pixels adaptive to the shape of the display panel, so that the light emitting effect at the boundary (boundaries) of the non-rectangular display panel is improved. Meanwhile, by making full advantage of sub-pixel sharing, actual number of the pixels in the display panel is increased and thus light emitting efficiency is improved.

### BRIEF DESCRIPTION OF THE DRAWINGS

The above and other features and advantages of the present disclosure will become clearer from detailed descriptions of exemplary embodiments with reference to drawings.

FIG. 1 is a schematic diagram showing a pixel array according to an embodiment of the present disclosure.

FIGS. 2A and 2B are schematic diagrams showing a pixel array according to an embodiment of the present disclosure.

FIGS. 3A to 3C are schematic diagrams showing a pixel array according to an embodiment of the present disclosure.

FIGS. 4A and 4B are schematic diagrams showing a pixel array according to an embodiment of the present disclosure.

FIGS. 5A and 5B are schematic diagrams showing a circular pixel arrangement according to an embodiment of the present disclosure.

FIGS. 6A and 6B are schematic diagrams showing a parallelogram-shaped pixel arrangement according to an embodiment of the present disclosure.

FIG. 7 is a schematic diagram showing a triangular pixel arrangement according to an embodiment of the present disclosure.

### DETAILED DESCRIPTION

Now, exemplary implementations will be described more comprehensively with reference to the accompanying drawings. However, the exemplary implementations may be carried out in various manners, and shall not be interpreted as being limited to the implementations set forth herein; instead, providing these implementations will make the present disclosure more comprehensive and complete and will fully convey the conception of the exemplary implementations to the ordinary skills in this art. Throughout the drawings, the like reference numbers refer to the same or the like structures, and repeated descriptions will be omitted.

The features, structures or characteristics described herein may be combined in one or more embodiments in any suitable manner. In the following descriptions, many specific details are provided to facilitate sufficient understanding of the embodiments of the present disclosure. However, one of ordinary skills in this art will appreciate that the technical solutions in the present disclosure may be practiced without one or more of the specific details, or by employing other methods, components, materials and so on. In other conditions, well-known structures, materials or operations are not shown or described in detail so as to avoid confusion of respective aspects of the present disclosure.

The drawings of the present disclosure are only for illustrating relative position relationships, and the sizes of some portions are shown exaggeratedly to facilitate understanding, and however the sizes in the drawings do not indicate real proportional relations.

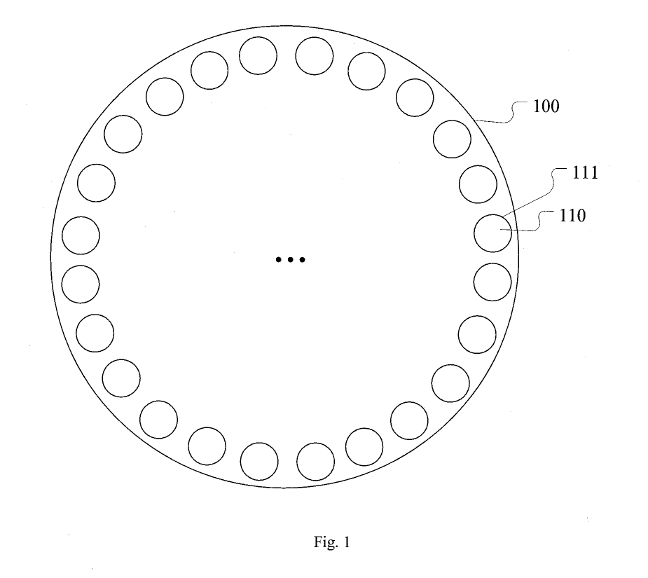

The present disclosure provides a pixel array, in which shapes of pixels at edges of the pixel array are changed to improve the display effect at the boundary of a non-rectangular OLED display panel. FIGS. 1 to 4B show different embodiments of the pixel array provided by the present disclosure, respectively.

FIG. 1 is a schematic diagram showing a pixel array according to an embodiment of the present disclosure. The pixel array is formed on a non-rectangular substrate 100. The pixel array includes a plurality of pixels. Specifically, the pixel array includes a plurality of edge pixels 110 arranged at an edge of the pixel array and a plurality of center pixels (not shown in FIG. 1) surrounded by the edge pixels 110. Each of the edge pixels 110 has a first boundary 111 facing a boundary of the non-rectangular substrate 100, and the shape of the first boundary 111 is adaptive to the shape of the non-rectangular substrate 100 so as to improve the display effect of the edge pixels. In the embodiment, the non-rectangular substrate 100 is of the same shape as that of each edge pixel 110, so that each of the edge pixels 110 has the first boundary 111 which is of a shape adaptive to that of the non-rectangular substrate 100. Specifically, both the non-rectangular substrate 100 and the edge pixels 110 have a circular shape, and then the first boundary 111 may be a semicircle boundary facing the boundary of the circular substrate 100.

In some embodiments, the center pixels may have the same shape as that of the edge pixels 110, i.e., the center pixels have a circular shape. However, in some other embodiments, the center pixels may have a shape different from that of the edge pixels 110. For example, the center pixels may have a rectangular shape, a triangular shape, a diamond shape, and the like.

In some embodiments, respective pixels in the pixel array may be arranged in rows and columns with pixels aligned with each other. In some modified embodiments, respective pixels in the pixel array may be staggered.

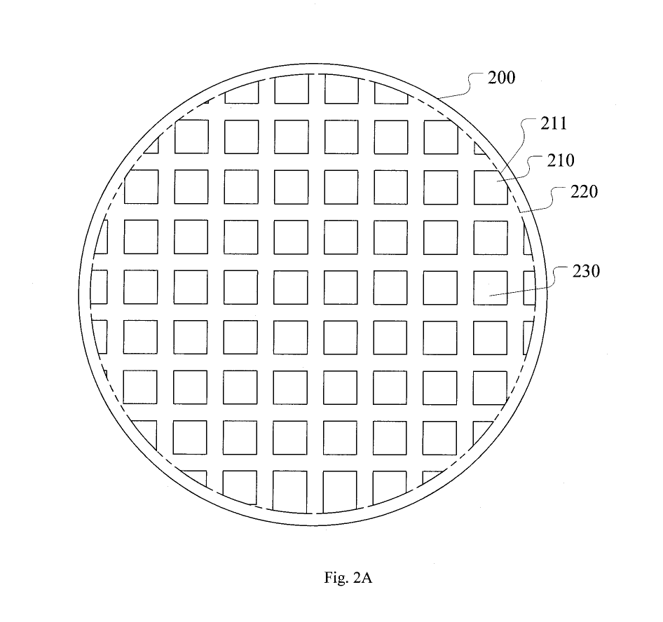

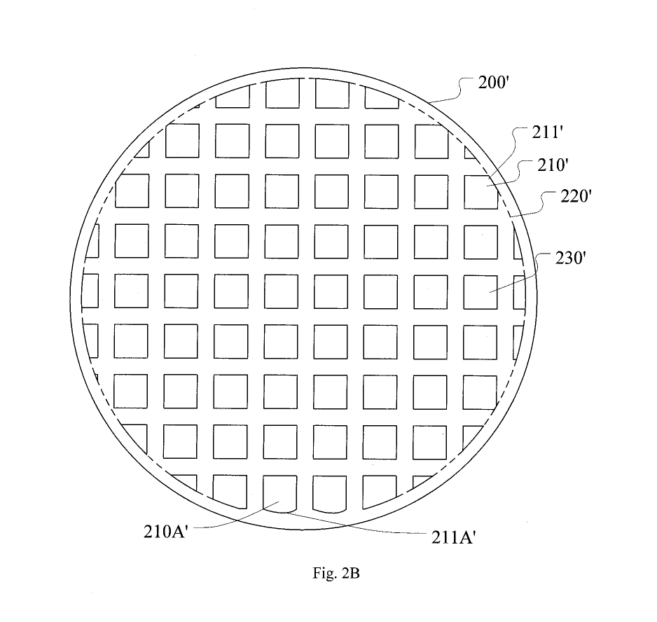

FIG. 2A is a schematic diagram showing a pixel array according to an embodiment of the present disclosure. The pixel is formed on a non-rectangular substrate 200. Similarly to FIG. 1, the pixel array includes a plurality of edge pixels 210 arranged at an edge of the pixel array and a plurality of center pixels 230 surrounded by the edge pixels 210. In the embodiment, distances between respective first boundaries 211 of the edge pixels 210 and the boundary of the non-rectangular substrate 200 which is adjacent to the first boundaries 211 are substantially the same, so that each edge pixel 210 has the first boundary 211 which is of a shape adaptive to that of the non-rectangular substrate 200. The adaptation of the shapes of the first boundaries 211 to the shape of the non-rectangular substrate 200 can improve the display effect of the pixel array. In the embodiment, the non-rectangular substrate 200 is circular and the boundary of the substrate 200 is curved (for example, the boundary is arched or rounded). Respective first boundaries 211 of the edge pixels 210 adjacent to the curved boundary are of the same curvature as that of the curved boundary.

Further, a connection line 220 for connecting the first boundaries 211 of respective edge pixels 210 is adaptive to the shape of the circular substrate 200, and thus the edge pixels 210 are arranged along the circumference of the substrate 200, and thereby the light emitting profile at the light emitting boundary of the pixel array (i.e., the shape formed by the connection line 220) is substantially the same as the shape of the boundary of the circle substrate 200. As a result, the display effect is improved. In the embodiment, the connection line 220 for connecting the first boundaries 211 of respective edge pixels 210 and the curved boundary of the circular substrate 200 have the same curvature, so that distances between the connection line 220 of the first boundaries 211 of the edge pixels 210 and the curved boundary of the circular substrate 200 are substantially the same. For example, the circle formed by the connection line 220 and the circle substrate 200 are concentric circles. It shall be noted that, the “connection line” in the context of the disclosure is an imaginary line which is not manufactured when pixels are formed, and the introducing of the term “connection line” is to define the light emitting profile at the light emitting boundary of the pixel array.

In the embodiment, the center pixels 230 have a shape different from that of the edge pixels 210. For example, the center pixels may have a rectangular shape, a triangular shape, a diamond shape, and the like. In some modified embodiments, the center pixels 230 and a part of the edge pixels 210 may have the same shape.

In the embodiment, respective pixels in the pixel array may be arranged in rows and columns with pixels aligned with each other. In some modified embodiments, respective pixels in the pixel array may be staggered. In some other modified embodiments, the pixels may be arranged according to varied arrangements.

FIG. 2B is a schematic diagram showing a pixel array according to an embodiment of the present disclosure. The pixel array shown in FIG. 2B is similar to that in FIG. 2A except for one difference that the distances between the first boundaries 211′ of the edge pixels 210′ and the boundary of the non-rectangular 200′ which is adjacent to the first boundaries 211′ are substantially the same, and the first boundaries 211A′ of the other part of the edge pixels 210A′ and the boundary of the non-rectangular 200′ which is adjacent to the first boundaries 211A′ have the same shape. In other words, the first boundaries 211′ of the part of edge pixels 210′ and the adjacent curved boundary have the same curvature, and the first boundaries 211A′ of the other part of edge pixels 210A′ are shaped as curved but have curvatures different from that of the curved boundary of the circular substrate 200′. The expression “same shape” in the context of the present disclosure refers to the same type of shape. For example, two boundaries (which are of the same shape) are curved but may have different curvatures. As another example, two boundaries (which are of the same shape) are rectangular but may have different length-width ratios. As a further example, two boundaries (which are of the same shape) are parallelogram-shaped but the ratios of two edges may be different.

Further, in the embodiment, only the connection lines 220′ for connecting the first boundaries 211′ of a part of the edge pixels 210′ and the curved boundary of the circular substrate 200′ have the same curvatures. For example, only the arc formed by connection lines 220′ of the first boundaries 211′ of a part of the edge pixels 210′ and the circular substrate 200′ have the same center.

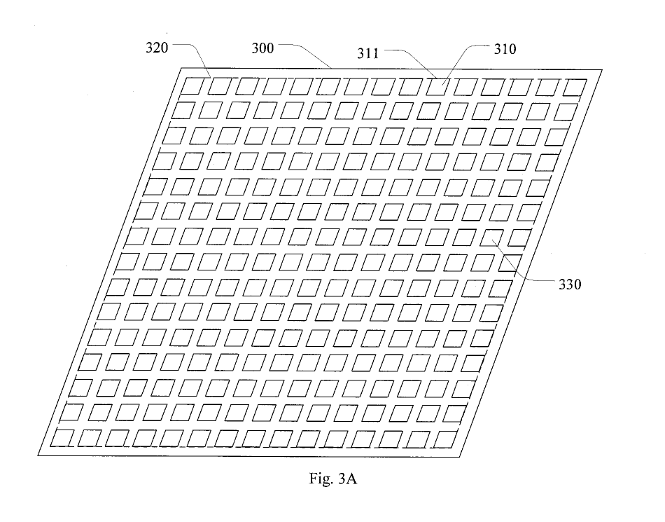

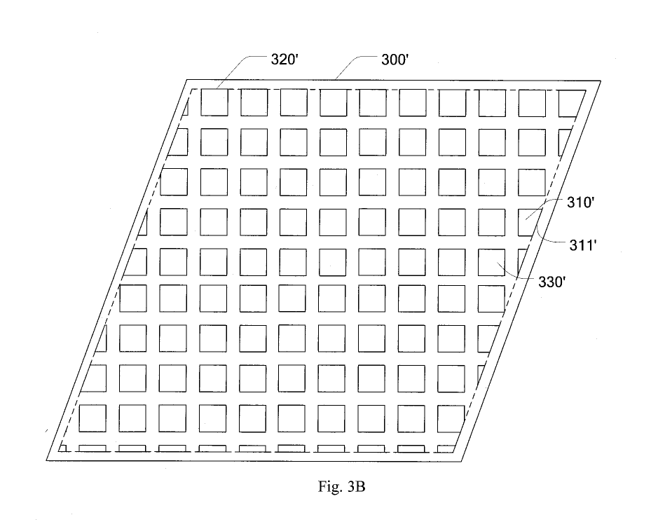

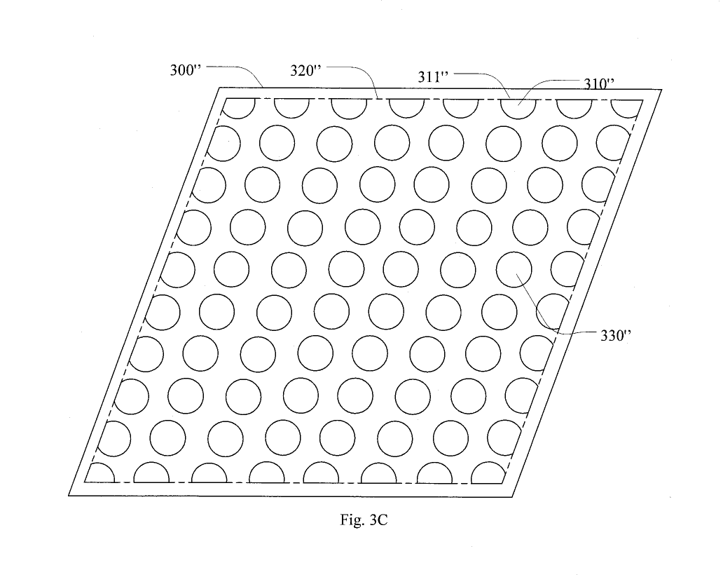

FIG. 3A is a schematic diagram showing a pixel array according to an embodiment of the present disclosure. In the embodiment, the non-rectangular substrate 300 is parallelogram-shaped. Edge pixels 310 have the same shape as that of the parallelogram-shaped substrate 300. That is, the edge pixels 310 have the same parallelogram shapes as the substrate 300. The expression “same shape” here refers to one shape is the same as another shape obtained by enlarging or shrinking the one shape in equal proportion. Distances between first boundaries 311 of the edge pixels 310 and the boundaries of the parallelogram-shaped substrate 300 which are adjacent to the first boundaries 311 are substantially the same. The first boundaries 311 are of the shapes adaptive to the shape of the parallelogram substrate 300 so as to improve the display effect of the pixel array. Specifically, in the embodiment, the first boundaries 311 of respective edge pixels 310 are in parallel with the boundaries of the parallelogram-shaped substrate 300 which are adjacent to the first boundaries 311.

Further, in the embodiment, the edge pixels 310 in the pixel array are arranged along directions of two adjacent edges of the parallelogram-shaped substrate 300, so that respective edges of a parallelogram formed by connection lines 320 for connecting the first boundaries 311 of the edge pixels 310 are in parallel with respective edges of the parallelogram-shaped substrate 300. Further, the distances between the connection lines 320 for connecting the first boundaries 311 of the edge pixels 310 and the boundaries of the parallelogram-shaped substrate 300 are substantially the same. Then, the light emitting profile at the light emitting boundaries of the pixel array (i.e., the shape formed by the connection lines 320) is substantially consistent with the boundary shapes of the parallelogram-shaped substrate 300, and thereby the display effect is improved. In some embodiments, the distances between respective edges of a parallelogram formed by connection lines 320 for connecting the first boundaries 311 of the edge pixels 310 and respective edges of the parallelogram-shaped substrate 300 are the same. In some modified embodiments, the distances between respective edges of a parallelogram formed by connection lines 320 for connecting the first boundaries 311 of the edge pixels 310 and respective edges of the parallelogram-shaped substrate 300 may be different.

In the embodiment, the center pixels 330 may have the same shape as that of the parallelogram-shaped substrate 300, and may be arranged along the directions of two adjacent edges of the parallelogram-shaped substrate 300. In some modified embodiments, the center pixels 330 may have a shape different from that of the parallelogram-shaped substrate 300. In some other modified embodiments, the center pixels 330 may be arranged according to varied arrangements and detailed descriptions are omitted herein.

FIG. 3B is a schematic diagram showing a pixel array according to an embodiment of the present disclosure. The pixel array in FIG. 3B is similar to that in FIG. 3A except for one difference: the edge pixels 310′ have a shape different from that of the parallelogram-shaped substrate 300′. The edge pixels 310′ have a polygonal shape, and first boundaries 311′ of the edge pixels 310′ are in parallel with the boundaries of the parallelogram-shaped substrate 300′ which are adjacent to the first boundaries 311′. Specifically, the edges pixels 310′ have a polygonal shape formed by cutting a rectangle along a line parallel with one edge of the parallelogram-shaped substrate 300′ or two lines parallel with two adjacent edges of the parallelogram-shaped substrate 300′.

Further, in the embodiment, respective edges of a parallelogram formed by connection lines 320′ for connecting the first boundaries 311′ of the edge pixels 310′ are in parallel with respective edges of the parallelogram-shaped substrate 300′.

In the pixel array as shown in FIG. 3B, pixels are arranged in rows and columns with pixels aligned with each other. In some modified embodiments, the pixels may be arranged along the directions of two adjacent edges of the parallelogram-shaped substrate 300′. The center pixels 330′ may have a shape different from that of the edge pixels 310′. For example, the center pixels 330′ may have a rectangular shape.

FIG. 3C is a schematic diagram showing a pixel array according to an embodiment of the present disclosure. The pixel array in FIG. 3C is similar to that in FIG. 3A except for one difference: the edge pixels 310″ have a shape different from that of the parallelogram-shaped substrate 300″. First boundaries 311″ of the edge pixels 310″ are in parallel with the boundaries of the parallelogram-shaped substrate 300″ which are adjacent to the first boundaries 311″. Specifically, the edges pixels 310 have an irregular shape formed by cutting a circle along a line parallel with one edge of the parallelogram-shaped substrate 300″ or two lines parallel with two adjacent edges of the parallelogram-shaped substrate 300″.

Further, in the embodiment, respective edges of a parallelogram formed by connection lines 320″ for connecting the first boundaries 311′ of the edge pixels 310″ are in parallel with respective edges of the parallelogram-shaped substrate 300″.

In the pixel array shown in FIG. 3C, the pixels are arranged along the directions of two adjacent edges of the parallelogram-shaped substrate 300″. The center pixels 330″ may have a shape different from that of the edge pixels 310″. For example, the center pixels 330″ may have a circular shape.

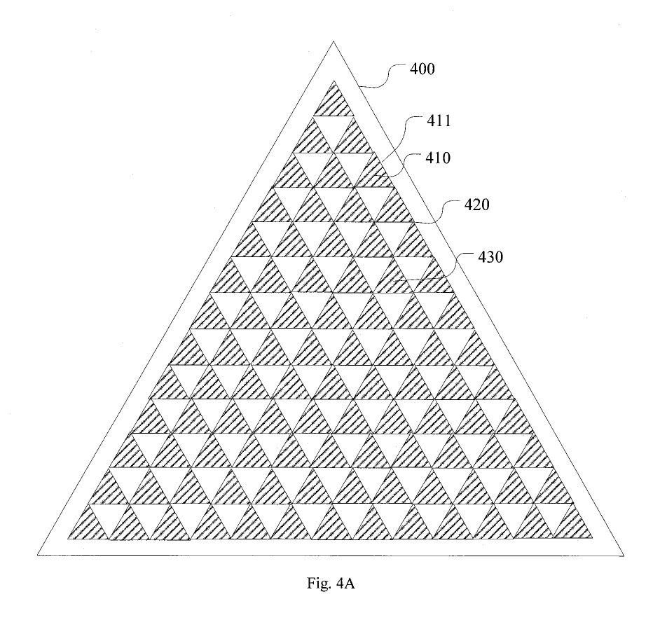

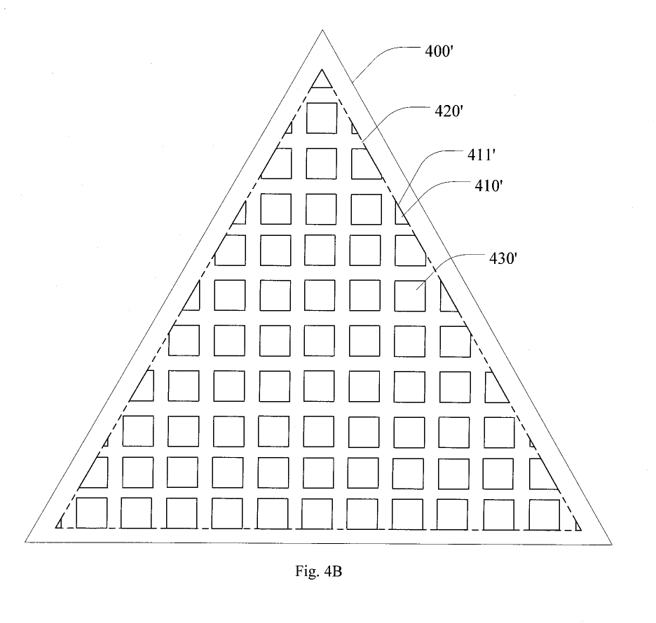

FIG. 4A is a schematic diagram showing a pixel array according to an embodiment of the present disclosure. In the embodiment, the non-rectangular substrate 400 has a triangular shape. Optionally, the non-rectangular substrate 400 is shaped as an equilateral triangle. The edge pixels 410 have the same shape as that of the triangular substrate 400. The distances between the first boundaries 411 of the edge pixels 410 and the boundaries of the triangular substrate 400 which are adjacent to the first boundaries 411 are substantially the same. The first boundaries 411 have a shape adaptive to the shape of the triangular substrate 400 so as to improve the display effect of the pixel array. Specifically, in the embodiment, the first boundaries 411 of edge pixels 410 are in parallel with the boundaries of the triangular substrate 400.

Further, in the embodiment, the edge pixels 410 in the pixel array are arranged in rows and columns with pixels aligned with each other, so that respective edges of a triangle formed by connection lines 420 for connecting the first boundaries 411 of the edge pixels 410 are in parallel with respective edges of the triangular substrate 400. Further, the distances between the connection lines 420 for connecting the first boundaries of the edge pixels 410 and the boundaries of the triangular substrate 400 are substantially the same. Then, the light emitting profile at the light emitting boundary of the pixel array (i.e., the shape formed by the connection lines 420) is substantially consistent with the boundary shape of the triangular substrate 400, and thus the display effect is improved. In some embodiments, the distances between respective edges of respective edges of a triangle formed by connection lines 420 for connecting the first boundaries 411 of the edge pixels 410 and respective edges of the triangular substrate 400 are the same. In some modified embodiments, the between respective edges of respective edges of a triangle formed by connection lines 420 for connecting the first boundaries 411 of the edge pixels 410 and respective edges of the triangular substrate 400 may be different.

In the embodiment, the center pixels 430 may have the same shape as that of the triangular substrate 400, and may be arranged in staggered rows and lines. In some modified embodiments, the center pixels 430 may have a shape different from that of the triangular substrate 400. In some other modified embodiments, the center pixels 430 may be arranged according to varied arrangement, and detailed descriptions are omitted herein.

FIG. 4B is a pixel array according to an embodiment of the present disclosure. The pixel array in FIG. 4B is similar to that in FIG. 4A except for one difference: the edge pixels 410 have a shape different from that of the triangular substrate 400′. The edge pixels 410′ have a polygonal shape and each has a first boundary 411′ parallel with a boundary of the triangular substrate 400′ which is adjacent to the first boundary 411′. Specifically, the edges pixels 410′ have polygonal shape formed by cutting a rectangle along a line parallel with one edge of the triangular substrate 400′ or two lines parallel with two adjacent edges of the triangular substrate 400′.

Further, in the embodiment, respective edges of a triangle formed by connection lines 420 for connecting the first boundaries 411′ of the edge pixels 410′ are in parallel with respective edges of the triangular substrate 400′.

In the pixel array as shown in FIG. 4B, the center pixels are arranged in rows and columns with pixels aligned with each other. In some modified embodiments, the center pixels may be arranged as staggered with each other. The center pixels 430′ may have a shape different from that of the edge pixels 410′. For example, the center pixels 430′ may have a rectangular shape.

One of ordinary skill in this art shall appreciate that the shape of the substrate is the same as that of the OLED display panel in the above embodiments. Particularly, in the process for manufacturing a plurality of panels simultaneously, the shape of the substrate in the present disclosure is the same as that of the OLED display panel after cutting process.

Pixel array for circular substrate, parallelogram-shaped substrate and triangular substrate are described in the above embodiments, and however, the present disclosure is not limited to this, one of ordinary skill in this art can realize pixel arrays for other polygonal substrates or substrates of other abnormal shapes based on the descriptions in the present disclosure, and these modified implementations shall be encompassed in the scope of the present disclosure.

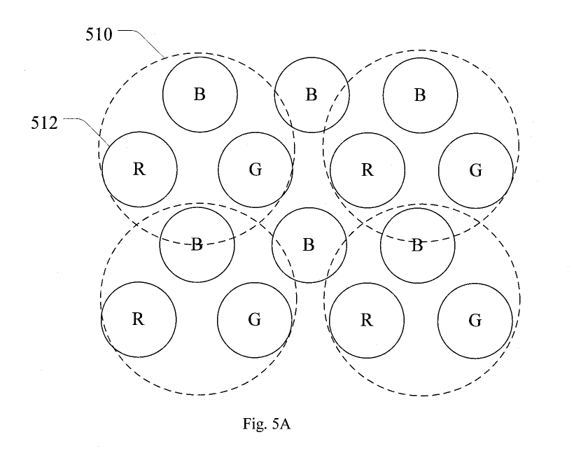

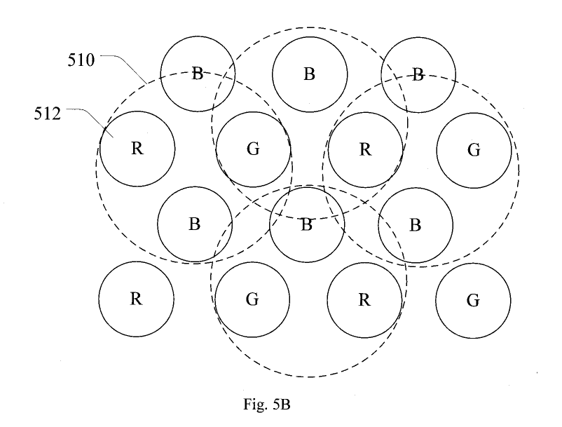

In order to better improve the display effect of an OLED display panel, the present disclosure further provides pixel arrays in which sub-pixels are shared. FIGS. 5A to 7 illustrate circular pixels, parallelogram-shaped pixels and triangular pixels, respectively, and mainly show the arrangement of center pixels and edge pixels which have the same shape as that of the non-rectangular substrate.

FIGS. 5A and 5B illustrate eight circular pixels 510 in a pixel array. For convenience in description, each of the two drawings shows a arrangement of four circle pixels 510. In the embodiment, the shapes of respective sub-pixels 512 and the shapes of the circle pixels 510 which are composed of the sub-pixels 512 are the same.

The sub-pixels 512 in the pixel array in FIGS. 5A and 5B are arranged as four rows of sub-pixels 512. The first row of sub-pixels include three blue sub-pixels B arranged along a row direction. The second row of sub-pixels include four sub-pixels, i.e., a red sub-pixel R, a green sub-pixel U, a red sub-pixel R, and a green sub-pixel G, which are arranged sequentially along the row direction. The third row of sub-pixels includes three blue sub-pixels B arranged along the row direction. The fourth row of sub-pixels includes fourth sub-pixels, i.e., a red sub-pixel R, a green sub-pixel G, a red sub-pixel R and a green sub-pixel G, which are sequentially arranged along the row direction. Among the sub-pixels, a blue sub-pixel B, a red sub-pixel R and a green sub-pixel G constitute a pixel. The four rows of sub-pixels as shown in FIGS. 5A and 5B may be arranged by sharing sub-pixels so as to form eight pixels.

Optionally, the number of the blue sub-pixels is greater than either of the number of the green sub-pixels G and the number of the red sub-pixels R. For example, in the arrangement of a part of sub-pixels 512 in the pixel array as shown in FIGS. 5A and 5B, the number of the blue sub-pixels B is six, the number of the red sub-pixels R is four, and the number of the green sub-pixels G is four.

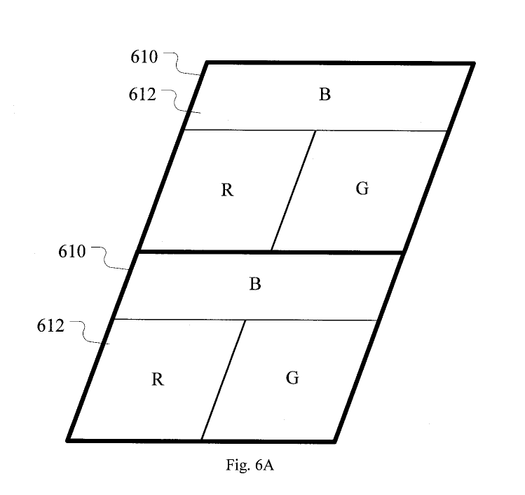

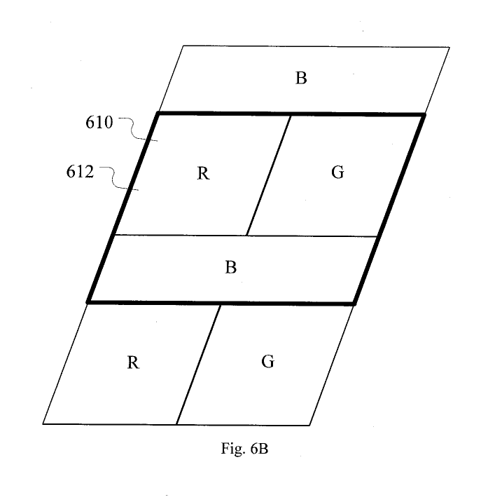

FIGS. 6A and 6B shows three parallelogram-shaped pixels 610 in a pixel array. In the embodiment, the shapes of the sub-pixels 612 are the same as that of the parallelogram-shaped pixels 610 composed of the sub-pixels 612. Specifically, the shapes of the red sub-pixels R and the green sub-pixels G are the same as that of the parallelogram-shaped pixels 610; the blue sub-pixels B have a parallelogram, and however, the ratio between two edges of the blue sub-pixels B and the ratio of two edges of the parallelogram-shaped pixels 610 are different.

The sub-pixels 612 in the pixel array in FIGS. 6A and 6B are arranged as four rows of sub-pixels 612. The first row includes one blue sub-pixels B. The second row of sub-pixels include two sub-pixels, i.e., a red sub-pixel R and a green sub-pixel G, which are arranged sequentially along the row direction. The third row includes one blue sub-pixels B. The fourth row of sub-pixels include two sub-pixels, i.e., a red sub-pixel R and a green sub-pixel G, which are sequentially arranged along the row direction. Among the sub-pixels, a blue sub-pixel B, a red sub-pixel R and a green sub-pixel G constitute a pixel. The four rows of sub-pixels as shown in FIGS. 6A and 6B may arranged by sharing sub-pixels so as to form three pixels. For example, the blue sub-pixel B in the first row, the red sub-pixel R in the second row, and the green sub-pixel G in the second row constitute a pixel 610; the blue sub-pixel B in the third row, the red sub-pixel R in the fourth row and the green sub-pixel G in the fourth row constitute a pixel 610 (see FIG. 6A); the red sub-pixel R in the second row, the green sub-pixel G in the second row and a blue sub-pixel B in the third row constitute a pixel 610 (see FIG. 6B).

Optionally, the blue sub-pixels have an area greater than that of the green sub-pixels G. Also, the areas of the blue sub-pixels B are greater than that of the red sub-pixels R. In some modified embodiments, the blue sub-pixels B may have the same area as that of the green sub-pixels G.

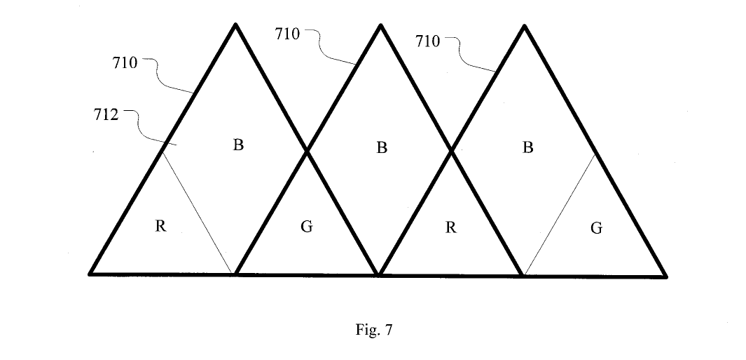

FIG. 7 shows three triangular pixels 710 in a pixel array. In the embodiment, a part of the sub-pixels 712 have the same shape as that of the triangular pixels 710 which are composed of the sub-pixels 712. Specifically, the shapes of the red sub-pixels R and the green sub-pixels G are the same as that of the triangular pixels 710, and the blue sub-pixels B are diamond shaped.

The part of sub-pixels 712 as shown in the pixel array of FIG. 7 are arranged as two rows. The first row of sub-pixels include three blue sub-pixels B arranged along the row direction. The second row of sub-pixels include four sub-pixels, i.e., a red sub-pixel R, a green sub-pixel, a red sub-pixel and a green sub-pixel G, which are sequentially arranged along the row direction. Among the sub-pixels, a blue sub-pixel B, a red sub-pixel R and a green sub-pixel G constitute a pixel. The sub-pixels as shown in FIG. 7 may be arranged by sharing sub-pixels so as to form three pixels. For example, the first blue sub-pixel B in the first row, the first red sub-pixel R in the second row and the first green sub-pixel G in the second row constitute a pixel 710; the second blue sub-pixel B in the first row, the first green sub-pixel G in the second row and the second red sub-pixel R in the second row constitute a pixel 710; the third blue sub-pixel B in the first row, the second red sub-pixel R in the second row and the second blue sub-pixel G in the second row constitute a pixel 710.

Optionally, the blue sub-pixels B have an area greater than that of the green sub-pixels G Also, the areas of the blue sub-pixels B are greater than that of the red sub-pixels R. In some modified embodiments, the blue sub-pixels B may have the same area as that of the green sub-pixels G.

Although circular pixels, parallelogram-shaped pixels and triangular pixels are described in the above embodiments, one of ordinary skill in this art can realize other modified implementations based on the descriptions in the present disclosure. For example, other pixels having abnormal shapes can be realized by sub-pixels sharing, and repeated descriptions are not elaborated here.

In the pixel array and display panel of the present disclosure, shapes and arrangement of pixels are changed to make shapes of pixels adaptive to the shape of the display panel, so that the light emitting effect at the boundary (boundaries) of the non-rectangular display panel is improved. Meanwhile, by making full advantage of sub-pixel sharing, actual number of the pixels in the display panel is increased and thus light emitting efficiency is improved.

The above detailed descriptions relate to some possible implementations of the present disclosure, and however they are not for limiting the protection scope of the present disclosure, and any equivalent implementations or modifications without departing the spirit of the present disclosure shall fall within the protection scope of the present disclosure.

What is claimed is:

1. A pixel array, formed on a non-rectangular substrate and comprising:
a plurality of edge pixels arranged at an edge of the non-rectangular substrate, each of which has a first boundary facing a boundary of the non-rectangular substrate, wherein the first boundary has a shape adaptive to a shape of the edge of the non-rectangular substrate; and
a plurality of center pixels surrounded by the plurality of edge pixels.

2. The pixel array according to claim 1, wherein distances between respective first boundaries of the edge pixels and the boundary of the non-rectangular substrate which is adjacent to the first boundaries are substantially the same.

3. The pixel array according to claim 2, wherein the non-rectangular substrate has a polygonal shape, and the first boundaries of the edge pixels are in parallel with the boundary of the non-rectangular substrate which is adjacent to the first boundaries.

4. The pixel array according to claim 2, wherein the boundary of the non-rectangular substrate is curved, and respective first boundaries of the edge pixels adjacent to the curved boundary are of the same curvature as that of the curved boundary.

5. The pixel array according to claim 1, wherein imaginary connection lines for connecting respective first boundaries of the edge pixels are adaptive to a shape of the non-rectangular substrate.

6. The pixel array according to claim 5, wherein distances between at least a part of the imaginary connection lines for connecting the first boundaries of the edge pixels and the boundary of the non-rectangular which is adjacent to the imaginary connection lines are substantially the same.

7. The pixel array according to claim 6, wherein the non-rectangular substrate has a polygonal shape, at least a part of the imaginary connection lines for connecting the first boundaries of the edge pixels are in parallel with the boundary of the non-rectangular substrate which is adjacent to the imaginary connection lines.

8. The pixel array according to claim 6, wherein the boundary of the non-rectangular substrate is curved, and the imaginary connection lines for connecting the first boundaries of the edge pixels adjacent to the curved boundary are of the same curvature as that of the curved boundary.

9. The pixel array according to claim 1, wherein the plurality of edge pixels have the same shape as that of the non-rectangular substrate.

10. The pixel array according to claim 1, wherein the plurality of center pixels have the same shape as that of at least part of the plurality of edge pixels.

11. The pixel array according to claim 1, wherein each of the pixels is composed of three sub-pixels of different colors.

12. The pixel array according to claim 11, wherein the different colors are red, blue and green.

13. The pixel array according to claim 12, wherein the number of the blue sub-pixels is greater than either of the number of the green sub-pixels and the number of the red sub-pixels.

14. The pixel array according to claim 12, wherein an area of each the blue sub-pixel is greater than either of an area of each green sub-pixel and an area of each red sub-pixel.

15. The pixel array according to claim 11, wherein at least a part of the sub-pixels are of the same shape as that of the pixels which are composed of the sub-pixels.

16. A display panel, comprising:
a non-rectangular substrate having the same shape as that of the display panel; and
a pixel array formed on the non-rectangular substrate and comprising:
a plurality of edge pixels arranged at an edge of the non-rectangular substrate, each of which has a first boundary facing a boundary of the non-rectangular substrate, wherein the first boundary has a shape adaptive to a shape of the edge of the non-rectangular substrate; and
a plurality of center pixels surrounded by the plurality of edge pixels.

17. The display panel according to claim 16, wherein distances between respective first boundaries of the edge pixels and the boundary of the non-rectangular substrate which is adjacent to the first boundaries are substantially the same.

18. The display panel according to claim 17, wherein the non-rectangular substrate has a polygonal shape, and the first boundaries of the edge pixels are in parallel with the boundary of the non-rectangular substrate which is adjacent to the first boundaries.

19. The display panel according to claim 17, wherein the boundary of the non-rectangular substrate is curved, and respective first boundaries of the edge pixels adjacent to the curved boundary are of the same curvature as that of the curved boundary.

20. The display panel according to claim 16, wherein imaginary connection lines for connecting respective first boundaries of the edge pixels are adaptive to a shape of the non-rectangular substrate.
